(19) United States
(12) Patent Application Publication
(10) Pub. No.: US 2025/0040312 A1
(43) Pub. Date: Jan. 30, 2025

(54) SEMICONDUCTOR DEVICE ARRANGEMENT STRUCTURE AND METHOD OF MANUFACTURING THE SAME

(71) Applicant: EPISTAR CORPORATION, Hsinchu (TW)

(72) Inventors: Tai-Ni CHU, Hsinchu (TW); Wei-Shan HU, Hsinchu City (TW); Ching-Tai CHENG, Hsinchu (TW)

(21) Appl. No.: 18/785,083

(22) Filed: Jul. 26, 2024

(30) Foreign Application Priority Data
Jul. 28, 2023 (TW) 112128375

(51) Int. Cl. H01L 33/48; H01L 25/075

(52) U.S. Cl. CPC H01L 33/483; H01L 25/0753

(57) ABSTRACT

A semiconductor device arrangement structure includes a carrier, a first semiconductor device, a second semiconductor device, a first adhesive part, and a second adhesive part. The first semiconductor device and the second semiconductor device are located on the carrier and separated from each other. The first adhesive part and the second adhesive part are separated from each other. The first adhesive part is located between the first semiconductor device and the carrier, and the second adhesive part is located between the second semiconductor device and the carrier. In a top view, the first adhesive part has a first outer contour surrounding the first semiconductor device. The first outer contour has at least one round corner.

### REFERENCE TO RELATED APPLICATION

This application claims priority to the benefit of Taiwan Application Number 112128375 filed on Jul. 28, 2023, the content of which are hereby incorporated by reference herein in its entirety.

### BACKGROUND

### Technical Field

The present disclosure relates to a semiconductor device arrangement structure, especially a semiconductor device arrangement structure on a carrier and the method of manufacturing the same.

### Description of the Related Art

Semiconductor devices, such as light-emitting diodes (LEDs), have low power consumption, low heat energy generation, long working life, shock resistance, small size, fast response speed, and good optoelectronic properties (such as stable luminescence wavelength) and other advantages. Therefore, it is widely used in electronic equipment such as household appliances, equipment indicators and displays.

In order to manufacture different electronic devices, a large number of light-emitting diodes need to be transferred between different bases. The steps usually include transferring a plurality of light-emitting diodes from a growth substrate to a temporary substrate, and the plurality of light-emitting diodes is fixed on the temporary substrate by an adhesive. Afterwards, an etching process is used to remove the adhesive between two adjacent light-emitting diodes.

However, in the etching process, in order to completely remove the adhesive between the two adjacent light-emitting diodes, the etching process often requires a long etching time, and the heat energy generated by the etching process may cause the light-emitting diodes to be tilted in the vertical direction or shifted in the horizontal direction. This not only makes the manufacturing process time-consuming and reduces yield, but is also detrimental to subsequent processes.

### BRIEF SUMMARY

According to an embodiment of the present disclosure, a semiconductor device arrangement structure is provided. The semiconductor device arrangement structure includes a carrier, a first semiconductor device, a second semiconductor device, a first adhesive part, and a second adhesive part. The first semiconductor device and the second semiconductor device are located on the carrier and separately from each other. The first adhesive part and the second adhesive part are separated from each other. The first adhesive part is located between the first semiconductor device and the carrier, and the second adhesive part is located between the second semiconductor device and the carrier. In a top view, the first adhesive part includes a first outer contour surrounding the first semiconductor device. The first outer contour includes at least one round corner.

According to an embodiment of the present disclosure, a method for manufacturing a semiconductor device arrangement structure is provided. The method for manufacturing a semiconductor device arrangement structure includes: providing a first supporting substrate, a first semiconductor device and a second semiconductor device located on the first supporting substrate and separated from each other; providing a second supporting substrate, the second supporting substrate including a carrier and an adhesive layer disposed on the carrier; moving the first semiconductor device and the second semiconductor device to make the first semiconductor device and the second semiconductor device contact the adhesive layer; heating the adhesive layer to transfer into a first adhesive part and a second adhesive part separated from the first adhesive part, and forming a gap part between the first adhesive part and the second adhesive part.

### BRIEF DESCRIPTION OF THE DRAWINGS

In order to make the following easier to understand, the drawings and their detailed text descriptions may be referred to simultaneously when reading this disclosure. Through the specific embodiments in this article and with reference to the corresponding drawings, the specific embodiments of the present disclosure are explained in detail, and the working principles of the specific embodiments of the present disclosure are explained. In addition, features in the drawings may not be drawn to actual scale for the sake of clarity, and therefore the dimensions of some features in some drawings may be intentionally exaggerated or reduced.

FIG. 1(a) is a top view of a semiconductor device arrangement structure according to some embodiments of the present disclosure.

FIG. 1(b) is an enlarged view of a partial area of FIG. 1(a) according to some embodiments of the present disclosure.

FIG. 2(a) is a cross-sectional view along line A-A′ of FIG. 1(b) according to some embodiments of the present disclosure.

FIG. 2(b) is a cross-sectional view along line B-B′ of FIG. 1(b) according to some embodiments of the present disclosure.

FIG. 3(a) is an enlarged view of a local area of FIG. 2(a) according to some embodiments of the present disclosure.

FIG. 3(b) is an enlarged view of a local area of FIG. 2(b) according to some embodiments of the present disclosure.

FIG. 4(a) is a cross-sectional view along cross line A-A′ of FIG. 1(b) of other embodiments of the present disclosure.

FIG. 4(b) is an enlarged view of a local area of FIG. 4(a) according to some embodiments of the present disclosure.

FIG. 5 is a partial enlarged view of a semiconductor device arrangement structure according to some embodiments of the present disclosure.

FIG. 6 is a top view of a plurality of semiconductor devices formed on a growth substrate at a certain process stage according to some embodiments of the present disclosure.

FIG. 7 is a cross-sectional view of different process stages of transferring a plurality of semiconductor devices from a growth substrate to a supporting substrate according to some embodiments of the present disclosure.

FIG. 8 is a top view and a cross-sectional view of a second supporting substrate at a certain process stage according to some embodiments of the present disclosure.

FIG. 9 is a cross-sectional view of different process stages of transferring a plurality of semiconductor devices from a first supporting substrate to a second supporting substrate according to some embodiments of the present disclosure.

FIG. 10 is a cross-sectional view of different process stages of transferring selected semiconductor device from a second supporting substrate to a third supporting substrate according to some embodiments of the present disclosure.

FIG. 11 is a cross-sectional view of different process stages of transferring a plurality of semiconductor devices from a first supporting substrate to a second supporting substrate according to other embodiments of the present disclosure.

### DETAILED DESCRIPTION

The present disclosure provides several different embodiments that can be used to implement different features of the disclosure. To simplify explanation, examples of specific components and arrangements are also described in this disclosure. These examples are provided for illustrative purposes only and are not intended to be limiting in any way. Various embodiments in the present disclosure may use repeated reference symbols and/or textual notations. These repeated reference symbols and notations are used to make the description more concise and clear, but are not used to indicate the correlation between different embodiments and/or configurations.

In addition, for the space-related descriptive words mentioned in this disclosure, such as: “under”, “top”, “bottom” and similar words are used to describe the relative relationship between one element or feature and another (or multiple) elements or features in the drawings for the convenience of description. In addition to the orientation shown in the drawings, these spatially related terms are also used to describe the orientation of components during use and operation. As each component is oriented differently (rotated 90 degrees or at other orientations), the description used to describe its orientation should be interpreted in a similar manner.

Although this disclosure uses terms such as first, second, third, etc. to describe elements, components, regions, layers, and/or sections, it should be understood that these elements, components, regions, layers, and/or or block shall not be limited by these terms. These terms are only used to distinguish one element, component, region, layer, and/or block from another element, component, region, layer, and/or block, and do not themselves imply or represent the element. There is no previous serial number, nor does it represent the order of arrangement of one component with another component, or the order of the manufacturing method. Therefore, a first element, component, region, layer, or block discussed below may also be termed a second element, component, region, layer, or block without departing from the scope of the specific embodiments of the disclosure.

Although the invention of the present disclosure is described below through specific embodiments, the inventive principles of the present disclosure can also be applied to other embodiments. In addition, in order not to obscure the spirit of the present invention, specific details will be omitted, and these omitted details fall within the scope of knowledge of those with ordinary skill in the art.

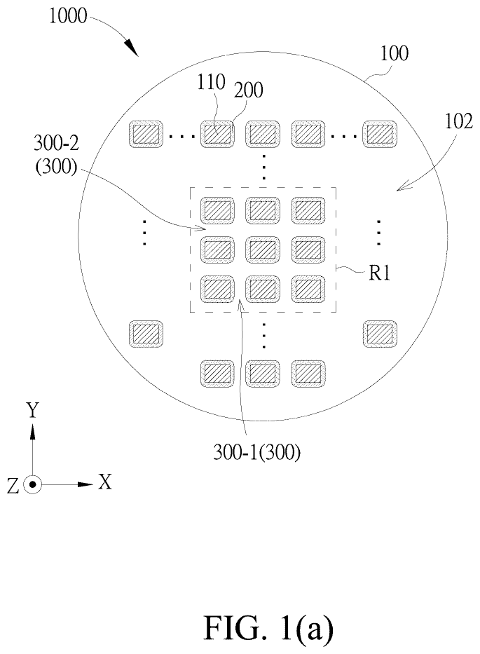

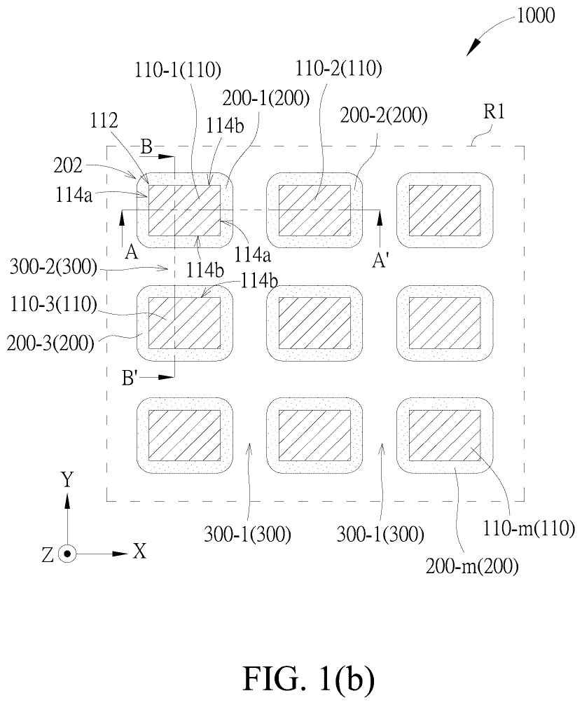

FIG. 1(a) is a top view of a semiconductor device arrangement structure according to some embodiments of the present disclosure, and FIG. 1(b) is an enlarged view of a partial area of FIG. 1(a). As shown in FIG. 1(a), the semiconductor device arrangement structure 1000 includes a carrier 100, a plurality of semiconductor devices 110 and a plurality of adhesive parts 200. The plurality of semiconductor devices 110 is separated from each other and located on the carrier 100. The plurality of adhesive parts 200 is separated from each other and is arranged between the corresponding semiconductor device 110 and the carrier 100. As shown in FIG. 1(b), each adhesive part 200 has an outer contour, and the outer contour surrounds the semiconductor device 110 and has at least one round corner 202, and the semiconductor device 110 has at least one sharp corner 112.

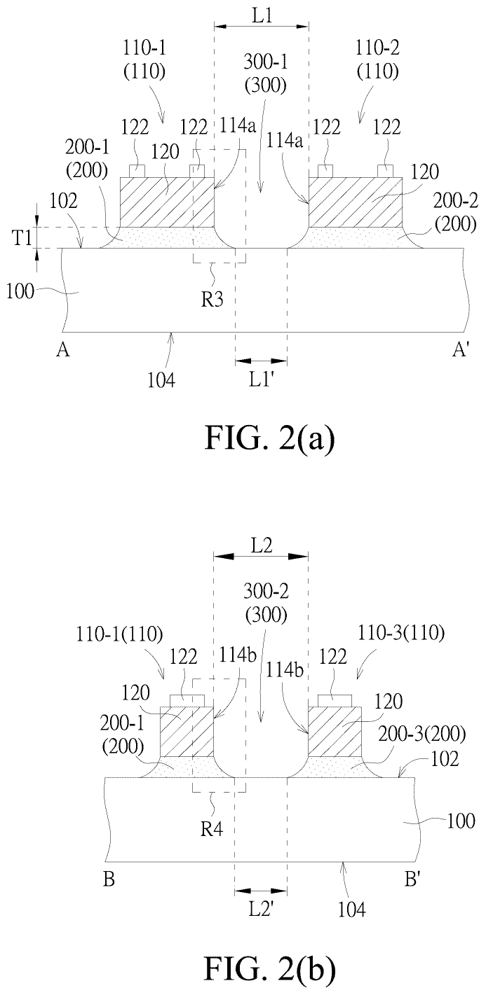

As shown in the top view of FIG. 1(a), the carrier 100 includes a front surface 102 and a back surface 104 (as shown in FIGS. 2(a) and 2(b)), and the plurality of semiconductor device 110 and the plurality of adhesive parts 200 are disposed on the front surface 102 of the carrier 100. According to some embodiments of the present disclosure, the carrier 100 is used to support the plurality of semiconductor devices 110. According to some embodiments of the present disclosure, the carrier 100 may include a non-epitaxial material or may be a non-growth substrate. For example, the carrier 100 may include ceramic substrate, metal substrate, glass substrate, thermal release tape, UV release tape, chemical release tape, heat-resistant tape, blue tape, or tape with a dynamic release layer (DRL). According to some embodiments of the present disclosure, the carrier 100 is able for laser light to penetrating therethrough, such as a glass substrate, a sapphire substrate, or a quartz substrate, so that the plurality of semiconductor devices 110 can be removed through a laser lift-off (LLO) process and separated from the carrier 100. According to some embodiments, when performing the laser lift-off process, the laser light can enter into the carrier 100 from the back surface 104 (as shown in FIGS. 2(a) and 2(b)) of the carrier 100, penetrate through the front surface 102 of the carrier 100, and irradiate to the adhesive parts 200 disposed on the front surface 102 for causing the adhesive parts 200 to partially or completely decompose or vaporize, so that one or multiple semiconductor device 110 is removed from the carrier 100. In addition, the carrier 100 is electrically insulated from the semiconductor device 110, so the electrical signals are not transmitted between the carrier 100 and the semiconductor device 110.

The semiconductor device 110 may include a transistor device or a semiconductor light-emitting device, such as a light-emitting diode. As shown in FIG. 1(a), two adjacent semiconductor devices 110 are separated from each other, and the shortest distance between the two adjacent semiconductor devices 110 in the same column or the same row is 1 μm to 50 μm. According to some embodiments, the shortest distance between two adjacent semiconductor devices 110 is less than a diagonal length of one semiconductor device 110 in a top view. For example, the shortest distance between two adjacent semiconductor devices 110 is 1/20 to ⅕ of the diagonal length of one of the semiconductor device 110. The plurality of semiconductor devices 110 is arranged in a specific layout or pattern on the carrier 100. For example, the plurality of semiconductor devices 110 is arranged in an array pattern on the carrier 100. According to some embodiments, the plurality of semiconductor devices 110 is arranged in a concentric pattern.

Two adjacent adhesive parts 200 are separated from each other and are used to fix the semiconductor devices 110 to the carrier 100. The plurality of adhesive parts 200 can be arranged in a specific layout or pattern, and the layout or pattern corresponds to the layout or pattern of the plurality of semiconductor devices 110. According to some embodiments, the plurality of adhesive parts 200 may be arranged in an array pattern or concentric pattern. The material of the adhesive part 200 may be a polymer. For example, the adhesive part 200 may include polyimide (PI), epoxy resin (EPO), polybenzoxazole (PBO), polysiloxane, cyclic olefin polymer (COP), or benzocyclobutane (BCB).

FIG. 1(b) is an enlarged view of region R1 in FIG. 1(a). In the region R1, the semiconductor devices 110 are arranged in a 3×3 array, that is 3 rows and 3 columns. There are gap parts 300 between two adjacent rows and between two adjacent columns of the semiconductor device 110. For example, a first gap part 300-1 between two adjacent columns of the semiconductor devices 110 and the second gap part 300-2 between two adjacent rows. According to some embodiments, each first gap part 300-1 extends along a first direction (Y direction), and each second gap part 300-2 extends along a second direction (X direction) different from the first direction. In addition, as shown in FIG. 1(b), the first gap part 300-1 and the second gap part 300-2 expose the front surface 102 of the carrier 100. Each semiconductor device 110 and each adhesive part 200 are surrounded by the gap parts 300.

As shown in FIG. 1(b), the plurality of semiconductor devices 110 includes a first semiconductor device 110-1, a second semiconductor device 110-2, a third semiconductor device 110-3 . . . and a m^{th} semiconductor device 110-m, where m is a positive integer greater than 3. The first semiconductor device 110-1 and the second semiconductor device 110-2 are located in the same column and are arranged along the X direction. The first semiconductor device 110-1 and the third semiconductor device 110-3 are located in the same row and are arranged along the Y direction. According to some embodiments, each semiconductor device 110 (such as the first semiconductor device 110-1, the second semiconductor device 110-2, and the third semiconductor device 110-3) includes a plurality of outermost edges, such as two first outermost edge 114a opposite to each other and the two second outermost edges 114b opposite to each other. The first outermost edge 114a connects to the second outermost edge 114b. According to some embodiments, each semiconductor device 110 (such as the first semiconductor device 110-1, the second semiconductor device 110-2, and the third semiconductor device 110-3) has a plurality of sharp corners 112. Each sharp corner 112 is formed by one first outermost edge 114a and one second outermost edge 114b. According to some embodiments, each semiconductor device 110 has a projected area in the Z direction, and the projected area is 50 μm2 to 5000 μm2.

As shown in FIG. 1b), the plurality of adhesive parts 200 includes the first adhesive part 200-1, the second adhesive part 200-2, the third adhesive part 200-3 . . . and the m^{th} adhesive part 200-m, where m is a positive integer greater than 3. The first adhesive part 200-1 and the second adhesive part 200-2 are located in the same column and are arranged along the X direction. The first adhesive part 200-1 and the third adhesive part 200-3 are located in the same row and are arranged along the Y direction. Each adhesive part 200 has an outer contour, an area of the outer contour is larger than that of the corresponding semiconductor device 110, and the outer contour surrounds the corresponding semiconductor device 110. That is, the first outermost edge 114a and the second outermost edge 114b of the semiconductor device 110 are located within the outer contour of the adhesive part 200. According to some embodiments, each adhesive part 200 (such as the first adhesive part 200-1, the second adhesive part 200-2, and the third adhesive part 200-3) has a plurality of round corners. According to some embodiments, each adhesive part 200 has a projected area in the Z direction larger than the projected area of the corresponding semiconductor device 110 in the Z direction. The projected area of the adhesive part 200 can be 55 μm2 to 6000 μm².

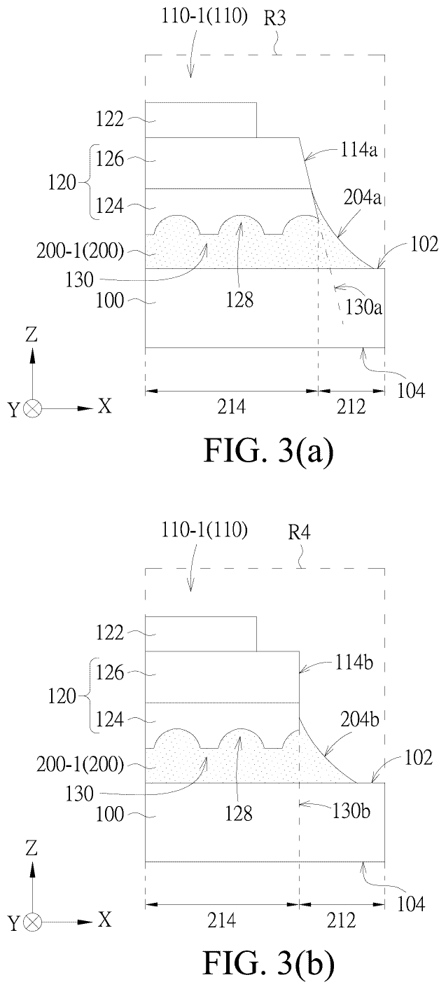

FIG. 2(a) and FIG. 2(b) respectively show cross-sectional views along cross line A-A′ and cross line B-B′ in FIG. 1(b). As shown in FIG. 2(a), the carrier 100 includes the front surface 102 and the back surface 104 opposite to the front surface 102. The first gap part 300-1 (300) is located between the first semiconductor device 110-1 and the second semiconductor device 110-2, and exposes the front surface 102 of the carrier 100. The first outermost edges 114a of the first semiconductor device 110-1 and the second semiconductor device 110-2 face each other, and a shortest distance L1 between the two facing first outermost edges 114a is 1 μm to 50 μm. According to some embodiments, the first semiconductor device 110-1 and the second semiconductor device 110-2 have the same or similar epitaxial structure. Each semiconductor device 110 includes a main body 120 and at least two electrode structures 122. The main body 120 includes a semiconductor stack (as shown in FIG. 3(a)) having a plurality of semiconductor layers stacked on each other (not shown). The electrode structure 122 is disposed on one side of the main body 120 (such as a front surface), and the adhesive part 200 is disposed on the other side of the main body 120 (such as a back surface opposite to the front surface). The electrode structure 122 may include a single-layer or multi-layer metal, and the electrode structure 122 includes at least one material selected from chromium (Cr), nickel (Ni), titanium (Ti), platinum (Pt), palladium (Pd), silver (Ag), gold (Au), aluminum (Al), and copper (Cu).

The structure of each semiconductor device 110 is not limited to the structure shown in FIG. 2(a) and FIG. 2(b). According to some embodiments, each semiconductor device 110 includes a redistribution layer (RDL) (not shown) formed on the front surface of the main body 120. The redistribution layer includes conductive interconnects, vias and bonding pads. The bonding pads may have specific layout patterns for forming specific conductive channels and electrically connecting to external circuits. In addition, according to some embodiments, each semiconductor device 110 may include a fan-out package structure, so the main body 120 includes at least one semiconductor stack and a encapsulating material surrounding the semiconductor stack.

The plurality of adhesive parts 200 is located between the semiconductor device 110 and the carrier 100. For example, the first adhesive part 200-1 is located between the first semiconductor device 110-1 and the carrier 100, and the second adhesive part 200-2 is located between the second semiconductor device 110-2 and carrier 100. According to some embodiments, the adhesive part 200 includes cross-linked and cured polymers, such as polyimide (PI), polyepoxide (EPO), polybenzoxazole (PBO), Polysiloxane, cyclic olefin polymer (COP), or benzocyclobutane (BCB). Each adhesive part 200 has a thickness T1 (or average thickness) of 50 nm to 2 μm. When the thickness T1 of the adhesive part 200 is too thin (depending on the material of the adhesive part 200), for example, when it is less than 50 nm, it may cause insufficient adhesion between the semiconductor device 110 and the carrier 100, and when the thickness T1 of the adhesive part 200 is too thick (depending on the material of the adhesive part 200), for example, when it is larger than 2 μm, two adjacent adhesive parts 200 may easily stick to each other. The shortest distance L1′ between the first adhesive part 200-1 and the second adhesive part 200-2 is 0.5 μm to 40 μm.

As shown in FIG. 2(b), the second gap part 300-2 (300) is located between the first semiconductor device 110-1 and the third semiconductor device 110-3. The two adjacent second outermost edges 114b of the first semiconductor device 110-1 and the third semiconductor device 110-3 face each other, and a shortest distance L2 between the two adjacent second outermost edges 114b is 1 μm to 50 μm. According to some embodiments, the first semiconductor device 110-1 and the third semiconductor device 110-3 have the same or similar epitaxial structure. According to some embodiments, the electrode structure 122 is disposed on one surface of the main body 120 (such as the front surface), and the adhesive part 200 is disposed on the other surface of the main body 120 (such as the back surface). The adhesive part 200 is located between the semiconductor device 110 and the carrier 100. For example, the first adhesive part 200-1 is located between the first semiconductor device 110-1 and the carrier 100, and the third adhesive part 200-3 is located between the third semiconductor device 110-3 and the carrier 100. A shortest distance L2′ between the first adhesive part 200-1 and the third adhesive part 200-3 is 0.5 μm to 40 μm.

FIG. 3(a) and FIG. 3(b) are cross-sectional views of some embodiments of the present disclosure, corresponding to the local areas of FIG. 2(a) and FIG. 2(b) respectively. The local area R3 in FIG. 3(a) corresponds to the local area R3 in FIG. 2(a), and the local area R4 in FIG. 3(b) corresponds to the local area R4 in FIG. 2(b). As shown in FIG. 3(a), according to some embodiments, the first semiconductor device 110-1 and other semiconductor device 110 are semiconductor light-emitting devices. The main body 120 of the first semiconductor device 110-1 includes a supporting substrate 124 and a semiconductor stack 126. The semiconductor stack 126 is disposed between the electrode structure 122 and the supporting substrate 124 and is electrically connected to the electrode structure 122. According to some embodiments, the semiconductor stack 126 sequentially includes a first semiconductor layer (not shown), a light-emitting layer (not shown), and a second semiconductor layer (not shown). The first semiconductor layer and the second semiconductor layer include dopants of different conductivity types, such as n-type dopants and p-type dopants, so that the first semiconductor layer and the second semiconductor layer can respectively supply electrons and holes.

According to some embodiments, a bottom surface of the supporting substrate 124 includes a plurality of depression areas 128 facing the carrier 100. Each depression area 128 has a diameter (D1) of 1 μm to 4 μm and a depth (D2) of 300 nm to 2 μm. The plurality of depression areas 128 has a repeating shape and is distributed over the entire bottom surface (along the X-Y plane) of the supporting substrate 124. By forming the plurality of depression areas 128, the luminous efficiency of the first semiconductor device 110-1 can be increased or the profile of the light distribution curve can be adjusted. In addition, since the first adhesive part 200-1 fills or fills up each depression area 128, the adhesion between the carrier 100 and the first semiconductor device 110-1 can be increased without changing the material or the overall thickness of the first adhesive part 200-1.

According to some embodiments, each adhesive part 200 (such as the first adhesive part 200-1) includes an overflow part 212 and a filling part 214. The overflow part 212 protrudes from the first outermost edge 114a of the first semiconductor device 110-1 and covers a part of the first outermost edge 114a, such as covering part of an outermost edge of the supporting substrate 124. According to some embodiments, the overflow part 212 has a curved side 204a recessed toward the carrier 100. According to some embodiments, the first outermost edge 114a is an inclined surface, and a virtual extension line 130a extending from the first outermost edge 114a to the carrier 100 is located within the curved side 204a. The filling part 214 is located between a bottom surface 130 of the first semiconductor device 110-1 and the carrier 100, and a maximum thickness T11 of the overflow part 212 is greater than a minimum thickness T12 of the filling part 214.

As shown in FIG. 3(b), according to some embodiments, the bottom surface of the supporting substrate 124 includes a plurality of depression areas 128 facing the carrier 100. The plurality of depression area 128 has a repeating shape and is distributed over the entire bottom surface (along the X-Y plane) of the supporting substrate 124. According to some embodiments, the overflow part 212 of the first adhesive part 200-1 protrudes from the second outermost edge 114b of the first semiconductor device 110-1 and covers a part of the second outermost edge 114b. According to some embodiments, the overflow part 212 has a curved side 204b recessed toward the carrier 100. According to some embodiments, the first outermost edge 114a includes a first slope and the second outermost edge 114b includes a second slope greater than the first slope of the first outermost edge 114a. For example, the second outermost edge 114b is a vertical plane The virtual extension line 130b extending from the second outermost edge 114b to the carrier 100 is located within the curved side 204b. The filling part 214 is located between the bottom surface 130 of the first semiconductor device 110-1 and the carrier 100, and a maximum thickness T13 of the overflow part 212 is greater than a minimum thickness T14 of the filling part 214.

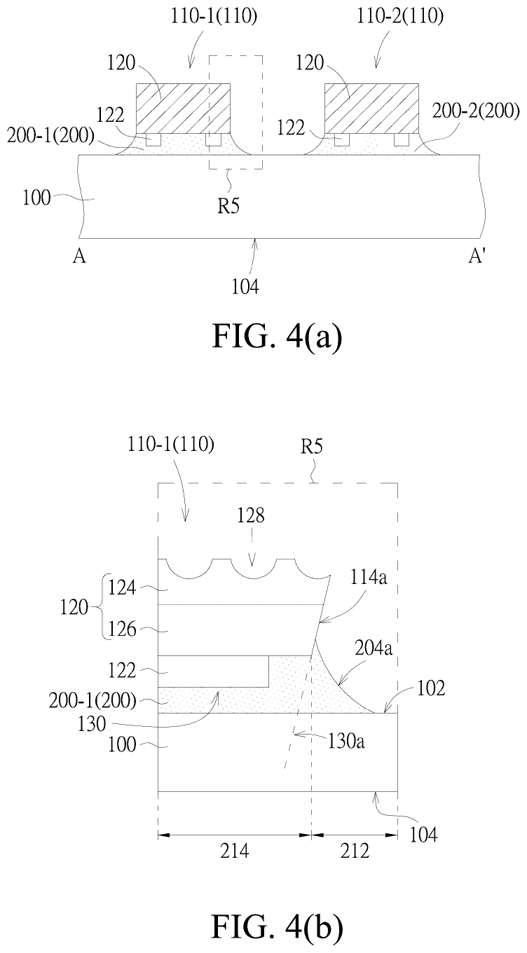

FIG. 4(a) is a cross-sectional view along cross line A-A′ of FIG. 1(b) of other embodiments of the present disclosure. As shown in FIG. 4(a), the semiconductor device arrangement structure is similar with that shown in FIG. 2(a), the main difference is that, the electrode structures 122 of the first semiconductor device 110-1 and the second semiconductor device 110-2 face the carrier 100 instead of being far away from the carrier 100. The electrode structures 122 are separated from the carrier 100 by the first adhesive part 200-1 and the second adhesive part 200-2, respectively.

FIG. 4(b) is an enlarged view of a local area R5 in FIG. 4(a). As shown in FIG. 4(b), the semiconductor device arrangement structure is similar with that shown in FIG. 3(a). The main difference is that, the depression area 128 of the supporting substrate 124 of the first semiconductor device 110-1 is away from the carrier 100 instead of facing the carrier 100. According to some embodiments, the overflow part 212 of the first adhesive part 200-1 protrudes from the first outermost edge 114a of the first semiconductor device 110-1 and covers a part of the first outermost edge 114a, such as covering an outermost edge of the semiconductor stack 126. According to some embodiments, the overflow part 212 has a curved side 204a recessed toward the carrier 100. According to some embodiments, the first outermost edge 114a is an inclined surface, and the virtual extension line 130a extending from the first outermost edge 114a to the carrier 100 is located within the curved side 204a. The filling part 214 is located between the electrode structure 122 of the first semiconductor device 110-1 and the carrier 100, and the maximum thickness of the overflow part 212 is greater than the minimum thickness of the filling part 214.

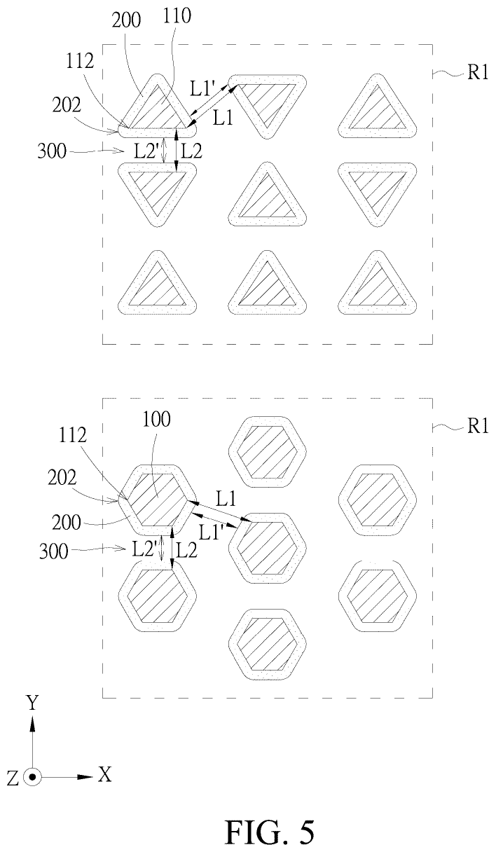

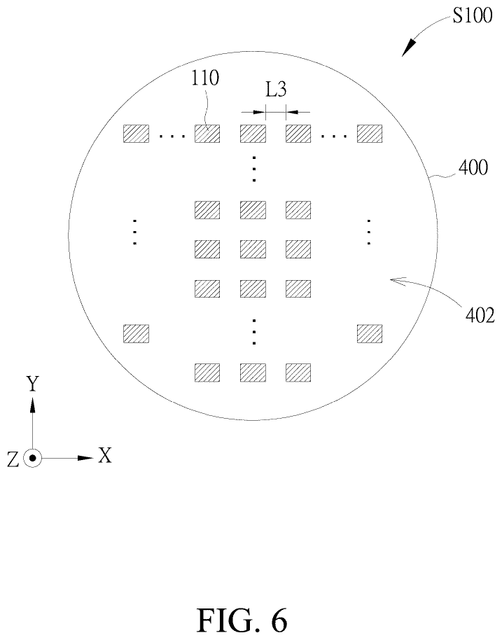

FIGS. 5(a) and 5(b) is a top view of a local area of a semiconductor device arrangement structure according to some embodiments of the present disclosure. The local area R1 shown in FIGS. 5(a) and 5(b) substantially corresponds to the local area R1 of FIG. 1(b). The main difference is that, the number of the sharp corners 112 of the semiconductor device 110 and the number of the round corners 202 of the adhesive part 200 are not 4, but are 3 in FIGS. 5(a) and 6 in FIG. 5(b). The positions of the sharp corners of the semiconductor device 110 and the round corners of the adhesive part 200 correspond to each other. According to some embodiments, the number of the sharp corners 112 of the semiconductor device 110 and the number of the round corners 202 of the adhesive part 200 can also be other positive integers. For example, each semiconductor device 110 has n sharp corners, and each adhesive part 200 has n round corners. The “n” is a positive integer greater than or equal to 3, and the n sharp corners of the semiconductor device 110 are respectively corresponding to the positions of the n rounded corners of the adhesive part 200. According to some embodiments, the shortest distances L1 and L2 between two adjacent semiconductor devices 110 range from 1 μm to 50 μm, and the shortest distances L1′ and L2′ between two adjacent adhesive parts 200 range from 0.5 μm to 40 μm.

In order to enable those with ordinary knowledge in the art to implement the present disclosure, the method for manufacturing the semiconductor device arrangement structure of the present disclosure is further described in detail below.

FIG. 6 is a top view of a plurality of semiconductor devices disposed on a growth substrate at a certain process stage according to some embodiments of the present disclosure. As shown in FIG. 6, in a step S100, a growth substrate 400 (which can be regarded as a support base) is provided, and a plurality of semiconductor devices 110 are formed on the front surface 402 of the growth substrate 400. According to some embodiments of the present disclosure, the growth substrate 400 includes a material which is suitable to conduct epitaxial processes. For example, the material of the growth substrate 400 can be silicon (Si), germanium (Ge), lithium aluminate (LiAlO2), zinc oxide (ZnO), silicon carbide (SiC), sapphire, gallium nitride (GaN), aluminum nitride (AlN), gallium arsenide (GaAs) or indium phosphorus (InP).

The two adjacent semiconductor devices 110 are separated from each other. According to some embodiments, the shortest distance L3 between adjacent semiconductor devices 110 is 1 μm to 50 μm, and the shortest distance L3 is less than the diagonal length of each semiconductor device 110 in a top view. For example, the shortest distance L3 between two adjacent semiconductor devices 110 is 1/20 to ⅕ of the diagonal length of each semiconductor device 110. The plurality of semiconductor devices 110 forms a specific arrangement layout, such as being arranged on the growth substrate 400 in an array pattern. According to some embodiments, the plurality of semiconductor devices 110 is arranged in a concentric pattern.

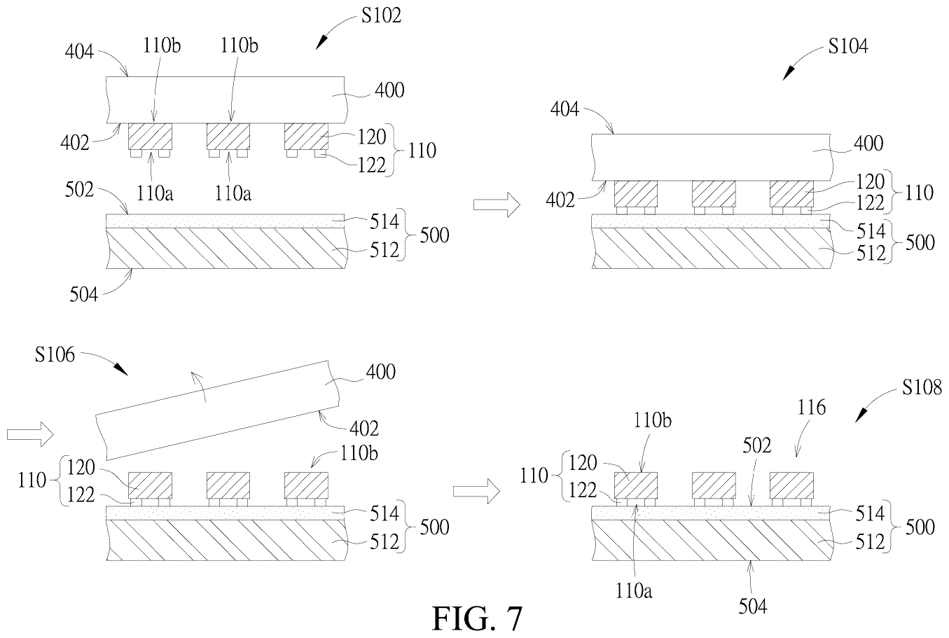

FIG. 7 is a cross-sectional view of different process stages of transferring the plurality of semiconductor devices from a growth substrate to a first supporting substrate according to some embodiments of the present disclosure. In a step S102, the semiconductor device 110 on the growth substrate 400 faces a first supporting base 500. According to some embodiments, the growth substrate 400 has a front surface 402 and a back surface 404 opposite to the front surface 402, and the semiconductor device 110 is formed on the front surface 402 of the growth substrate 400. The semiconductor device 110 has a front surface 110a and a back surface 110b opposite to the front surface 110a, the front surface 110a is away from the growth substrate 400, and the back surface 110b faces the growth substrate 400. The first supporting base 500 has a front surface 502 and a back surface 504 opposite to the front surface 502. The front surface 502 faces the growth substrate 400, and the back surface 504 is away from the growth substrate 400. The first supporting base 500 may include a non-epitaxial material or a non-growth substrate. For example, the first supporting base 500 can be a ceramic substrate, a metal substrate, a glass substrate, a thermal release tape, a UV release tape, or chemical removal tape, chemical release tape, heat-resistant tape, blue tape, or tape with a dynamic release layer (DRL). According to some embodiments, the first supporting base 500 includes a carrier 512 and a first connecting layer 514. The carrier 512 has sufficient mechanical strength to carry the first connecting layer 514. The first connecting layer 514 has sufficient adhesiveness to secure components that are pressed thereto.

In the step S104, at least one of the growth substrate 400 and the first supporting base 500 is moved so that the semiconductor device 110 contacts the first supporting base 500 and is fixed to the first connecting layer 514. According to some embodiments, a thermal pressing process may be used so that the semiconductor device 110 is fixed to the first connecting layer 514 of the first supporting base 500.

In the step S106, a separation process is performed to separate the growth substrate 400 from the semiconductor device 110 and expose the back surface 110b of the semiconductor device 110. According to some embodiments, a laser lift-off process can be used to irradiate laser light from the back surface 404 to the front surface 402 of the growth substrate 400, to vaporize a semiconductor material between the semiconductor device 110 and the growth substrate 400 and separate the semiconductor device 110 from the growth substrate 400. The semiconductor material can be gallium nitride, aluminum nitride or other compound semiconductor materials.

In the step S108, a cleaning process is performed on the semiconductor device 110 to remove semiconductor residues or metal residues, such as gallium-containing particles, remaining on the back surface 110b of the semiconductor device 110. Therefore, it is possible to prevent the light extraction efficiency of the semiconductor device 110 from being affected by the semiconductor residues or metal residues with low light transmittance.

Through the steps S106 to S108 shown in FIG. 7, a plurality of semiconductor devices 110 (including at least the first semiconductor device and the second semiconductor device) are transferred from the growth substrate 400 (which can be regarded as a supporting base) to the first supporting base 500. The plurality of semiconductor devices 110 is located on the first supporting base 500 and is separated from each other. According to some embodiments, the arrangement of the semiconductor device 110 on the first supporting base 500 may be similar or identical to the arrangement of the semiconductor device 110 on the growth substrate 400.

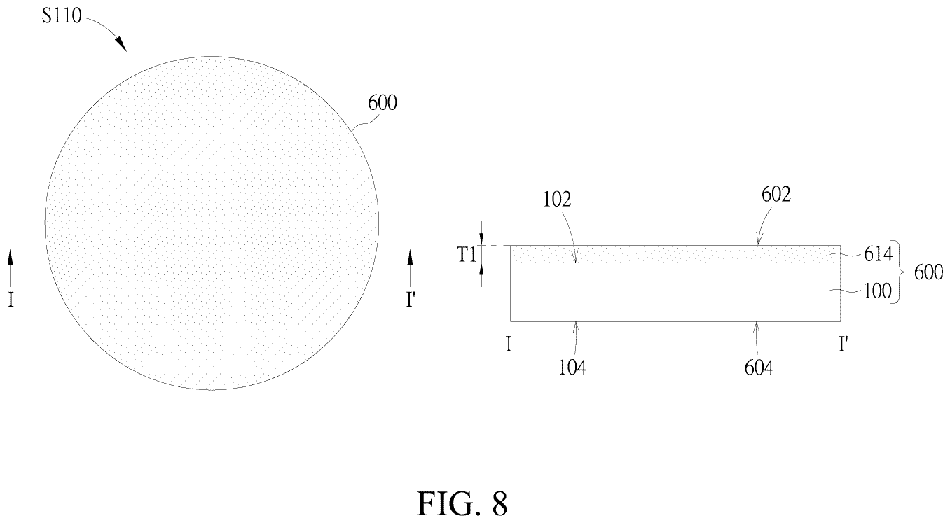

FIG. 8 is a top view and a cross-sectional view of the second supporting substrate at a certain process stage according to some embodiments of the present disclosure. As shown in FIG. 8, in the step S110, a second supporting base 600 is provided. The second supporting base 600 has a front surface 602 and a back surface 604 opposite to the front surface 602. The second supporting base 600 includes a carrier 100 and an adhesive layer 614 continuously distributed on the carrier 100. The adhesive layer 614 is disposed on the front surface 102 of the carrier 100 and has a uniform thickness, such as 50 nm to 2 μm. According to some embodiments, the adhesive layer 614 contains a cross-linking agent and an un-cross-linked polymer. The un-cross-linked polymer includes polyimide (PI), polyepoxide (EPO), polybenzoxazole (PBO), polysiloxane, cyclic olefin polymer (COP), or benzocyclobutane (BCB). According to some embodiments, the adhesive layer 614 is made by spin coating to apply a liquid adhesive material to the front surface 102 of the carrier 100, and then soft baking is preformed to remove a part of the solvent in the liquid adhesive material, so that the adhesive layer 614 can be fixed on the carrier 100.

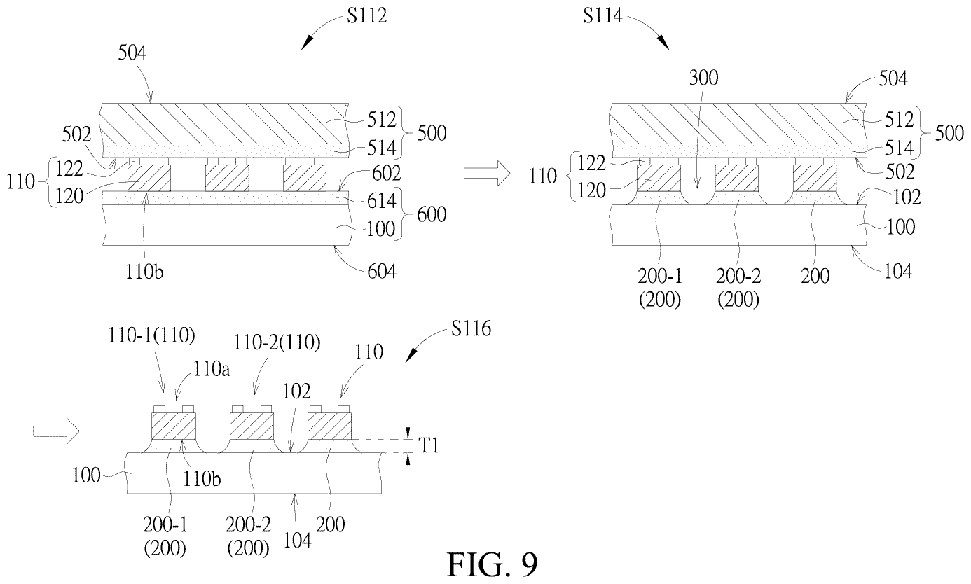

FIG. 9 is a cross-sectional view of different process stages of transferring a plurality of semiconductor devices from a first supporting substrate to a second supporting substrate according to some embodiments of the present disclosure. In the step S112, the front surface 502 of the first supporting base 500 faces the front surface 602 of the second supporting base 600, and at least one of the first supporting base 500 and the second supporting base 600 is moved so that the semiconductor device 110 located on the first supporting base 500 is able to contact the second supporting base 600. By performing the step S112, the thickness of the adhesive layer 614 between two adjacent semiconductor devices 110 may be slightly increased by 5% to 30%. However, when the thickness of the adhesive layer 614 between two adjacent semiconductor devices 110 is increased by more than 50%, the two adjacent semiconductor devices 110 may not be able to be individually removed from the carrier 512 in the following process, which adversely affect the transferring process of the semiconductor devices 110.

Next, referring to step S114, when the first supporting base 500 and the second supporting base 600 are pressed together, a thermal process is performed so that the adhesive layer 614 forms separate adhesive parts 200, which include the first adhesive part 200-1 and the second adhesive part 200-2. According to some embodiments, in the early stage of the thermal process, the viscosity of the adhesive layer 614 is reduced and becomes fluid. Due to the surface tension, the adhesive layer 614 deforms during the thermal process and aggregates toward the adjacent semiconductor device 110 (also known as self-aggregation), and splits from a single continuous layer into at least two parts separated from each other. For example, the adhesive parts 200 are separated from each other, and the front surface 102 of the carrier 100 located between adjacent semiconductor devices 110 is exposed. In other words, during the thermal process, the area covered by the adhesive layer 614 on the carrier 100 is reduced. When the adhesive parts 200 continues to be heated, the degree of cross-linking between the uncross-linked polymers within the adhesive parts 200 gradually increases, which causes the viscosity of the adhesive parts 200 to increase until the adhesive parts 200 solidifies into solid adhesive parts 200. There is a gap part 300 forming between the solid adhesive parts 200 and parts of the front surface 102 of the carrier 100 are exposed.

According to some embodiments, since there is a plurality of depression areas (such as the depression areas 128 shown in FIG. 3(a) and FIG. 3(b)) on the back surface 110b of the semiconductor device 110, during the thermal process of the step S114, the fluid adhesive layer 614 may fill the depression area 128 due to capillary action, thereby increasing the adhesion between the semiconductor device 110 and the adhesive parts 200.

In the step S116, a separation process is performed to separate the first supporting base 500 from the semiconductor device 110, and expose the front surface 110a of the semiconductor device 110. According to some embodiments, a laser lift-off process can be used to irradiate laser light from the back surface 504 to the front surface 502 of the first supporting base 500, to decompose or vaporize the first connecting layer 514 between the semiconductor device 110 and the carrier 512, and the semiconductor device 110 is separated from the first supporting base 500, resulting in a semiconductor device arrangement structure 1000 similar to that shown in FIG. 1(a) and FIG. 1(b).

According to some embodiments of the present disclosure, the adhesive layer 614 will self-aggregate to form separate adhesive parts 200. Therefore, the etching process for the adhesive parts 200 between two adjacent semiconductor devices 110 can be omitted, or the etching time can be significantly reduced when the etching process is performed. In addition, since the etching process is eliminated or the etching time is reduced, it is possible to avoid tilt or shift of the semiconductor device 110 due to external forces generated by the etching process.

According to the above manufacturing method of the semiconductor device arrangement structure, the semiconductor device 110 is first transferred from the growth substrate 400 to the first supporting base 500, and then transferred to the second supporting base 600. According to some embodiments, the growth substrate 400 can be regarded as a supporting base, and the semiconductor device 110 can be transferred directly from the growth substrate 400 to the second supporting base 600.

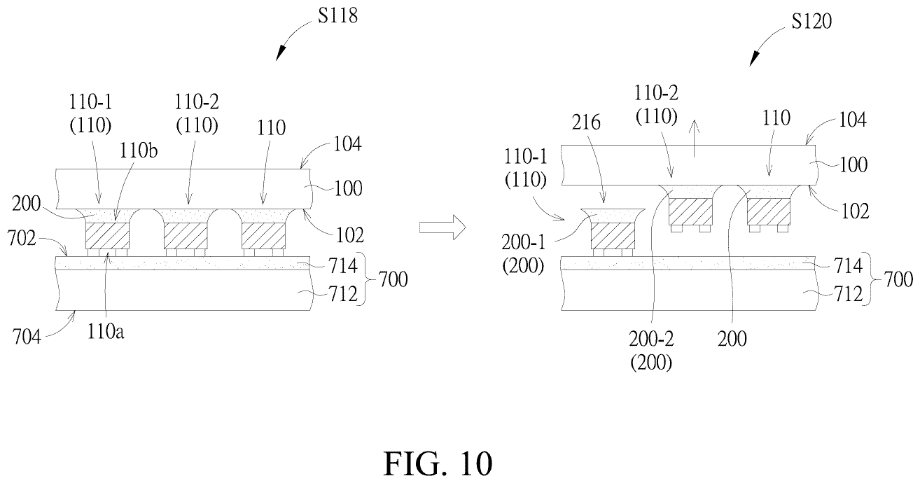

After completing the semiconductor device arrangement structure shown in the step S116, some of the semiconductor devices 110 on the second supporting base 600 can be selectively and individually transferred to other supporting substrates to perform a grouping process where the semiconductor devices have similar or identical electrical properties or optical properties. The steps are similar with those shown in FIG. 10.

FIG. 10 is a cross-sectional view of different process stages of transferring a semiconductor device from a second supporting substrate to a third supporting substrate according to an embodiment of the present disclosure. In the step S118, the plurality of semiconductor devices 110 on the carrier 100 faces the third supporting substrate 700. According to some embodiments, the third supporting substrate 700 has a front surface 702 and a back surface 704 opposite to the front surface 702, the front surface 702 faces the carrier 100, and the back surface 704 is away from the carrier 100. The third supporting substrate 700 may be a non-epitaxial material or a non-growth substrate. For example, the third supporting substrate 700 may be a ceramic substrate, a metal substrate, a glass substrate, a thermal release tape, a photolysis adhesive film (UV Release Tape), a chemical removal tape, a chemical release tape, a heat-resistant tape, a blue tape, or tape with a dynamic release layer (DRL). According to one embodiment, the third supporting substrate 700 includes a carrier 712 and a second connecting layer 714. The carrier 712 has sufficient mechanical strength to carry the second connecting layer 714. The second connecting layer 714 has sufficient adhesiveness to secure components that are pressed thereto. Then, when the front surface 102 of the carrier 100 faces the front surface 702 of the third supporting substrate 700, at least one of the carrier 100 and the third supporting substrate 700 is moved so that the semiconductor devices 110 located on the carrier 100 contacts the second connecting layer 714 of the third supporting substrate 700.

In the step S120, a separation process is performed to transfer the selected semiconductor device 110 (such as the first semiconductor device 110-1) from the carrier 100 to the third supporting substrate 700, and expose a back surface 216 of the first adhesive part 200-1. Other unselected semiconductor devices 110 (such as the second semiconductor device 110-2) still stay on the front surface 102 of the carrier 100. According to some embodiments, a laser lift-off process can be used to irradiate the selected first semiconductor device 110-1 with a laser light to decompose or vaporize the first adhesive part 200-1 between the first semiconductor device 110-1 and the carrier 100, so that the first semiconductor device 110 is separated from the carrier 100. The unselected semiconductor devices 110 will not be irradiated by the laser light, so they still stay on the front surface 102 of the carrier 100. According to some embodiments, in the subsequent process, other selected semiconductor devices 110 (such as the second semiconductor device 110-2) can continue to be transferred from the carrier 100 to other supporting substrates (not shown), and the transfer process can be repeated until all the semiconductor devices 110 located on the carrier 100 are transferred to the selected one or more supporting substrates.

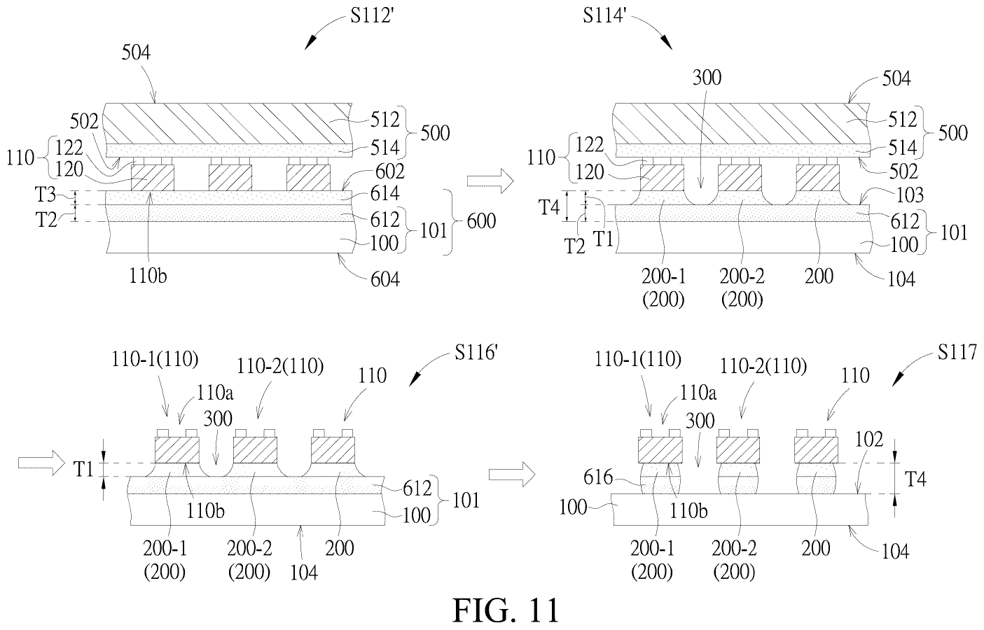

FIG. 11 is a cross-sectional view of different process stages of transferring a plurality of semiconductor devices from a first supporting substrate to a second supporting substrate according to another embodiments of the present disclosure. In this embodiment, a polymer layer 612 may be additionally disposed between the carrier 100 and the adhesive layer 614. The corresponding process can be referred to FIG. 11 and the process steps in FIG. 11 can be regarded as derived from the process steps in FIG. 9. The differences between two embodiments are described below.

In the step S112′, the plurality of semiconductor devices 110 is located on the first supporting base 500, and the semiconductor devices 110 located on the first supporting base 500 contact the adhesive layer 614 of the second supporting base 600.

The first connecting layer 514 of the first supporting base 500 may be a sticky elastomer, such as polysiloxane. In addition to being used for fixing the semiconductor device 110, the first connecting layer 514 can also elastically deform when an external force is applied to the first connecting layer 514.

The second supporting base 600 includes the carrier 100, the polymer layer 612 and the adhesive layer 614. The polymer layer 612 is disposed between the carrier 100 and the adhesive layer 614 and adjacent to the adhesive layer 614. The combination of the polymer layer 612 and the carrier 100 can also be regarded as a composite carrier 101. A thickness T2 of the polymer layer 612 may be greater than, less than, or equal to a thickness T3 of the adhesive layer 614. The polymer layer 612 and the adhesive layer 614 may be derived from the same adhesive material but undergo different processes. For example, before performing step S112′, the polymer layer 612 has gone through soft baking and hard baking processes and is completely cross-linked and solidified. Therefore, even if a thermal process or a thermal pressing process is subsequently performed, the polymer layer 612 will not have fluidity. In contrast, before step S112′ is performed, the adhesive layer 614 has only undergone a soft baking process and has not yet been completely cross-linked. Therefore, the adhesive layer 614 will have fluidity when a subsequent thermal process or thermal pressing process is performed.

In the step S112′, the semiconductor devices 110 located on the first supporting base 500 contact the adhesive layer 614 of the second supporting base 600. At this time, the thickness T2 of the polymer layer 612 will not change while applying pressing process 110, but the thickness T3 of the adhesive layer 614 may change while applying pressure to the semiconductor device 110.

Next, referring to step S114′, the first supporting base 500 and the second supporting base 600 are pressed together, and a thermal process is performed so that the adhesive layer 614 forms separate adhesive parts 200 including the first adhesive part 200-1 and the second adhesive part 200-2. According to some embodiments, in the early stage of the thermal process, the viscosity of the adhesive layer 614 is reduced and becomes fluid. Due to the surface tension, the adhesive layer 614 deforms during the thermal process and aggregates toward the adjacent semiconductor device 110, and form the adhesive parts 200 that are separated from each other, and the polymer layer 612 located between two adjacent semiconductor devices 110 is exposed from the gap part 300. The polymer layer 612 has an exposed surface 103. When the adhesive parts 200 continues to be heated, the degree of cross-linking between the uncross-linked polymers in the adhesive parts 200 gradually increases, which causes the viscosity of the adhesive parts 200 to continue to increase until the adhesive parts 200 solidifies into solid adhesive parts 200.

After performing this thermal process, the thickness T1 of the adhesive part 200 may be different from the thickness T3 (or the average thickness) of the adhesive layer 614. In comparison, the thickness T2 (or the average thickness) of the polymer layer 612 remains unchanged before or after the thermal process. In one embodiment, when the thickness T1 of the adhesive part 200 is larger than the thickness T3 (or the average thickness) of the adhesive layer 614, by providing the polymer layer 612, the total thickness T4 of the polymer layer 612 and the adhesive part 200 can be increased without increasing the thickness T3 of the adhesive layer 614. Thereby, the adhesive layer 614 can be prevented from overflowing due to being too thick, thereby preventing two adjacent adhesive parts 200 from being connected to each other.

On the other hand, since the first connecting layer 514 of the first supporting base 500 is an elastomer, during the pressing process, the applied force can be evenly dispersed by the elastomer to each semiconductor device 110, so that the thickness T1 of the adhesive part 200 under each semiconductor device 110 is substantially the same. For example, the thickness deviation between the thicknesses T1 is less than 3%. Therefore, it is beneficial to the subsequent adhesive layer removal process of each semiconductor device 110.

In the step S116′, a separation process is performed to separate the first supporting base 500 from the semiconductor device 110 and expose the front surface 110a of the semiconductor device 110.

Next, referring to the step S117, an etching process, such as a plasma etching process, is performed to remove the polymer layer 612 at a position corresponding to the gap part 300 to form the patterned polymer layer 616 to expose the front surface 102 of the carrier 100 located between the two adjacent semiconductor devices 110. During the etching process, the sidewall of the adhesive part 200 will also be etched, thereby changing its cross-sectional profile.

In the embodiment shown in FIG. 11, the adhesive part 200 and the patterned polymer layer 616 are located on the back surface 110b of the semiconductor device 110. According to different processes and requirements, the adhesive part 200 and the patterned polymer layer 616 may also be located on the front surface 110a of the semiconductor device 110 instead of the back surface 110b.

After completing the semiconductor device arrangement structure shown in step S117, each semiconductor device 110 on the carrier 100, together with the adhesive part 200 and the patterned polymer layer 616, can be further transferred to other supporting substrates (not shown) to group the semiconductor devices 110 with similar or identical electrical properties or optical properties. Among them, the adhesive part 200 and the patterned polymer layer 616 on the semiconductor device 110 are arranged away from the supporting substrate. Afterwards, a dry adhesive layer removal process, such as a plasma adhesive layer removal process, may be performed to remove the adhesive part 200 and the patterned polymer layer 616 located on the semiconductor device 110. Since the total thicknesses T4 of the adhesive part 200 and the patterned polymer layer 616 of each semiconductor device 110 are substantially the same., it is not easy to occur the situation that some shielded surfaces (such as the front surface 110a or the back surface 110b) of a part of the plurality of semiconductor devices 110 being exposed by the adhesive part 200, but some shielding surfaces of other parts of the plurality of semiconductor devices 110 still being covered by the adhesive part 200 through preforming the adhesive layer removal process. Therefore, the front or back surfaces of the semiconductor device 110 can be prevented from reacting with the plasma, and the original electrical performance of the semiconductor device 110 can be maintained after the adhesive layer removal process.

According to embodiments of the present disclosure, the adhesive layer on the carrier can be heated to cause the adhesive layer to deform due to its own surface tension and aggregate toward the adjacent semiconductor devices, thereby splitting from the original single continuous layer into separate parts. A surface of the carrier between two adjacent semiconductor devices is exposed. Since the two adjacent adhesive parts may form separate self-isolating structures through self-aggregation, the etching process for the adhesive parts between two adjacent semiconductor devices can be eliminated when isolating each semiconductor device, or etching time can be greatly reduced. Since the etching process is eliminated or the etching time of the etching process is shortened, the tilt or deflection of the semiconductor devices caused by the etching process can be also avoided.

The above are only preferred embodiments of the present disclosure, and all equivalent changes and modifications made in accordance with the patentable scope of the present disclosure shall fall within the scope.

1. A semiconductor device comprising:
arrangement structure,
a carrier;
a first semiconductor device and a second semiconductor device being separately from each other and located on the carrier; and
a first adhesive part and a second adhesive part separated from each other, and the first adhesive part located between the first semiconductor device and the carrier, and the second adhesive part located between the second semiconductor device and the carrier;
wherein, in a top view, the first adhesive part comprises a first outer contour surrounding the first semiconductor device, and the first outer contour comprises at least one round corner.

2. The semiconductor device arrangement structure of claim 1, wherein the first semiconductor device comprises a projected area ranging from 50 μm² to 5000 μm².

3. The semiconductor device arrangement structure of claim 1, wherein the first adhesive part comprises:
an overflow part protruding from a first outermost edge of the first semiconductor device; and
a filling part located between the first semiconductor device and the carrier;
wherein the overflow part comprises a maximum thickness larger than a smallest thickness of the filling part.

4. The semiconductor device arrangement structure of claim 1, wherein in a cross-sectional view, the first semiconductor device comprises a first outermost edge, and the first adhesive part has a curved side corresponding to the first outermost edge, and a virtual extension line of the first outermost edge extending toward the carrier locates within the curved side.

5. The semiconductor device arrangement structure of claim 4, wherein the curved side of the first adhesive part is recessed toward the carrier.

6. A method of manufacturing a semiconductor device arrangement structure, comprising:
providing a first supporting substrate, a first semiconductor device and a second semiconductor device on the first supporting substrate and separated from each other;
providing a second supporting substrate, and the second supporting substrate comprising a carrier and an adhesive layer on the carrier;
contacting the first semiconductor device and the second semiconductor device to the adhesive layer;
heating the adhesive layer to transfer into a first adhesive part and a second adhesive part separated from the first adhesive part, and form a gap between the first adhesive part and the second adhesive part.

7.-10. (canceled)

11. The semiconductor device arrangement structure of claim 3, wherein in a cross-sectional view, the overflow part covers a part of the first outermost edge.

12. The semiconductor device arrangement structure of claim 1, wherein the carrier comprises a bottom surface of the supporting substrate including a plurality of depression areas facing the carrier or away from the carrier.

13. The semiconductor device arrangement structure of claim 1, wherein the semiconductor device comprises a sharp corner corresponding to the round corner of the first adhesive part.

14. The semiconductor device arrangement structure of claim 1, wherein the first semiconductor device further comprises a second outermost edge connecting to the first outermost edge, and the second outermost edge comprises a first slope, and the second outermost edge comprises a second slope greater than the first slope.

15. The semiconductor device arrangement structure of claim 1, wherein the first semiconductor device comprises a main body and an electrode structure, and the electrode structure is disposed on one surface of the main body, and the first adhesive part is disposed on the other surface of the main body.

16. The semiconductor device arrangement structure of claim 1, wherein the first semiconductor device comprises a main body and an electrode structure, and the electrode structure is separated from the carrier by the first adhesive part.

17. The semiconductor device arrangement structure of claim 1, wherein the first outer contour has 3˜6 round corners.

18. The semiconductor device arrangement structure of claim 1, wherein in a top view, the first semiconductor device comprises a diagonal length larger than a shortest distance between the first semiconductor device and the second semiconductor device.

19. The semiconductor device arrangement structure of claim 13, wherein the shortest distance between the first semiconductor device and the second semiconductor device is 1/20 to ⅕ of the diagonal length of the first semiconductor device.

20. The semiconductor device arrangement structure of claim 1, further comprising a polymer layer between the first adhesive part and the carrier.

21. The method of manufacturing a semiconductor device arrangement structure of claim 6, wherein the second supporting substrate further comprising a polymer layer between the carrier and the adhesive layer.

22. The method of manufacturing a semiconductor device arrangement structure of claim 17, further comprising an etching process to remove a part of the polymer layer corresponding to the gap and form a patterned polymer layer.

23. The method of manufacturing a semiconductor device arrangement structure of claim 18, wherein a cross-sectional profile of a sidewall of the first adhesive part changes by the etching process.

24. The method of manufacturing a semiconductor device arrangement structure of claim 16, wherein the carrier is exposed after heating the adhesive layer.
